(19) United States
(12) Patent Application Publication
(10) Pub. No.: US 2024/0046130 A1
(43) Pub. Date: Feb. 8, 2024

(54) SIMULATION METHOD, ELECTRONIC DEVICE, AND STORAGE MEDIUM

(71) Applicant: Beijing Baidu Netcom Science Technology Co., Ltd., Beijing (CN)

(72) Inventors: Lijing JIN, Beijing (CN); Yuxuan WANG, Beijing (CN)

(21) Appl. No.: 18/193,909

(22) Filed: Mar. 31, 2023

(30) Foreign Application Priority Data
Aug. 4, 2022 (CN) 202210934648.0

(51) Int. Cl. G06N 10/20; G06N 10/40; G06F 30/392

(52) U.S. Cl. CPC G06N 10/20; G06N 10/40; G06F 30/392

(57) ABSTRACT

Provided is a simulation method, an electronic device and a storage medium, relating to the field of computer and in particular to the field of quantum computer and quantum simulation. The simulation method can includes obtaining first frequency information of a first target device among at least two devices of a quantum chip layout through simulation, and obtaining second frequency information of a second target device among the at least two devices through simulation; and obtaining a coupling strength between the first target device and the second target device among the at least two devices based on the first frequency information and the second frequency information.

### CROSS-REFERENCE TO RELATED APPLICATIONS

The present application claims priority to Chinese Patent Application No. 202210934648.0, filed with the China National Intellectual Property Administration on Aug. 4, 2022, the disclosure of which is hereby incorporated herein by reference in its entirety.

### TECHNICAL FIELD

The present disclosure relates to the field of computing, and in particular to the field of quantum computers and quantum simulation.

### BACKGROUND

In the entire layout design of a quantum chip, the design of characteristic parameters is an important part. For example, the design of coupling strength between different devices is a top priority. Therefore, there is an urgent need for a solution to conveniently obtain the coupling strength between target devices in a quantum chip layout.

### SUMMARY

The present disclosure provides a simulation method and apparatus, device and storage medium.

According to an aspect of the present disclosure, provided is a simulation method, including: obtaining first frequency information of a first target device among at least two devices of a quantum chip layout through simulation, and obtaining second frequency information of a second target device among the at least two devices through simulation; and obtaining a coupling strength between the first target device and the second target device among the at least two devices based on the first frequency information and the second frequency information.

According to another aspect of the present disclosure, provided is a simulation apparatus, including: a simulation unit configured to obtain first frequency information of a first target device among at least two devices of a quantum chip layout through simulation, and obtain second frequency information of a second target device among the at least two devices through simulation; and a calculation unit configured to obtain a coupling strength between the first target device and the second target device among the at least two devices based on the first frequency information and the second frequency information.

According to yet another aspect of the present disclosure, provided is an electronic device, including: at least one processor; and a memory connected in communication with the at least one processor; where the memory stores an instruction executable by the at least one processor, and the instruction, when executed by the at least one processor, enables the at least one processor to execute the method of any of the embodiments of the present disclosure.

According to yet another aspect of the present disclosure, provided is a non-transitory computer-readable storage medium storing a computer instruction thereon, and the computer instruction causes a computer to execute the method of any of the embodiments of the present disclosure.

According to yet another aspect of the present disclosure, provided is a computer program product including a computer program, and the computer program implements the method of any of the embodiments of the present disclosure, when executed by a processor.

In this way, the coupling strength between each target device (such as the first target device and the second target device) in the quantum chip layout can be readily obtained without modeling a complex quantum chip layout. The techniques described herein are particularly applicable to scenarios where there are a large number of qubits (quantum bits) in the quantum chip layout.

It will be understood that this summary is not intended to identify key or important features of any of the embodiments of the present disclosure, nor does it limit the scope of the present disclosure. Other features of the present disclosure will be easily understood by the following detailed description.

### BRIEF DESCRIPTION OF THE DRAWINGS

The accompanying drawings are used to better understand the present solution, and do not constitute a limitation to the present disclosure.

FIG. 1 is a first schematic diagram of an implementation flow of a simulation method according to an embodiment of the present disclosure.

FIG. 2 is a second schematic diagram of an implementation flow of a simulation method according to an embodiment of the present disclosure.

FIG. 3 is a third schematic diagram of an implementation flow of a simulation method according to an embodiment of the present disclosure.

FIG. 4 is a fourth schematic diagram of an implementation flow of a simulation method according to an embodiment of the present disclosure.

FIG. 5(a) and FIG. 5(b) are schematic structural diagrams of a quantum chip layout according to an embodiment of the present disclosure.

FIG. 6 is a schematic diagram of an implementation flow of a simulation method in a specific example according to an embodiment of the present disclosure.

FIG. 7(a) is a schematic structural diagram of a quantum chip layout in Example 1 according to an embodiment of the present disclosure.

FIG. 7(b) is a comparison diagram of a simulation result obtained by the solution of the present disclosure in Example 1 and a simulation result of an existing solution.

FIG. 7(c) is a comparison diagram of a simulation result obtained by the solution of the present disclosure in Example 2 and a simulation result of the existing solution.

FIG. 8(a) is a schematic structural diagram of a quantum chip layout in Example 3 according to an embodiment of the present disclosure.

FIG. 8(b) is a comparison diagram of a simulation result obtained by the solution of the present disclosure in Example 3 and a simulation result of the existing solution.

FIG. 9 is a schematic structural diagram of a simulation apparatus according to an embodiment of the present disclosure.

FIG. 10 is a block diagram of an electronic device used to implement the simulation method of the embodiments of the present disclosure.

### DETAILED DESCRIPTION

Hereinafter, descriptions to exemplary embodiments of the present disclosure are made with reference to the accompanying drawings, include various details of the embodiments of the present disclosure to facilitate understanding, and should be considered as merely exemplary. Therefore, those having ordinary skill in the art should realize, various changes and modifications may be made to the embodiments described herein, without departing from the scope and spirit of the present disclosure. Likewise, for clarity and conciseness, descriptions of well-known functions and structures are omitted in the following descriptions.

The term “and/or” herein only describes an association relation of associated objects, which indicates that there may be three kinds of relations, for example, A and/or B may indicate that only A exists, or both A and B exist, or only B exists. The term “at least one” herein indicates any one of many items, or any combination of at least two of the many items, for example, at least one of A, B or C may indicate any one or more elements selected from a set of A, B and C. The terms “first” and “second” herein indicate a plurality of similar technical terms and distinguish them from each other, but do not limit an order of them or limit that there are only two items, for example, a first feature and a second feature indicate two types of features/two features, a quantity of the first feature may be one or more, and a quantity of the second feature may also be one or more.

In addition, in order to better illustrate the present disclosure, numerous specific details are given in the following specific implementations. Those having ordinary skill in the art should understand that the present disclosure may be performed without certain specific details. In some examples, methods, means, elements and circuits well known to those having ordinary skill in the art are not described in detail, in order to highlight the subject matter of the present disclosure.

As a landmark technology in the post-Moore era, the research and development of quantum computing has attracted much attention from academia and industry. Compared with traditional computing, the quantum computing has significant advantages in solving difficult problems such as decomposition of large numbers, and also brings a new idea to frontier research such as quantum many-body and quantum chemical simulation. Various potential quantum applications have greatly promoted the development of quantum hardware. In terms of hardware implementation, the industry has a variety of candidate technical solutions, such as a superconducting quantum circuit, ion trap, diamond NV color center, nuclear magnetic resonance, optical quantum system, and so on. Benefiting from advantages such as long decoherence time, easy manipulation/reading and strong expandability, the superconducting quantum circuit is considered to be one of the most promising candidates for quantum computing hardware.

As the core carrier of the technology solution of the superconducting quantum circuit, the development of a superconducting quantum chip integrating a plurality of qubits (quantum bits) is crucial. With the development of micro-nano processing technology, the quantity of qubits that can be integrated on the superconducting quantum chip has increased from a few to dozens and hundreds. In the future, the integration of thousands of qubits will eventually be realized. Facing demand for an ever-increasing quantity of qubits, the necessity and urgency of designing a superconducting quantum chip layout has become increasingly apparent.

In the entire layout design of the superconducting quantum chip, the design of characteristic parameters is an important part. Specific characteristic parameters include frequency and nonlinear strength of a qubit, frequency of a read cavity, quality factor of the qubit and the read cavity, and so on. In addition, design of the coupling strength between different devices is also important. An example is the design of the coupling strength between neighbor qubits (or adjacent qubits, referring to qubits directly coupled with each other, or qubits directly coupled through a coupler, etc.), because the coupling strength between neighbor qubits is closely related to the fidelity of a two-bit quantum gate; another example is the design of the coupling strength between non-neighbor qubits (or non-adjacent qubits, for example, two qubits are not directly coupled but indirectly coupled through one or more intermediate qubits, and at this time, the two indirectly coupled qubits can be called non-neighbor qubits), because the coupling strength between non-neighbor qubits is helpful to characterize and mitigate the crosstalk problem; and yet another example is the design of the coupling strength between the qubit and the read cavity, because the coupling strength between the qubit and the read cavity is crucial to the fidelity and efficiency of qubit reading.

Therefore, before micro-nano processing, it is necessary to determine the coupling strength between two target devices from the simulation level. However, the existing common method is: firstly conducting equivalent circuit modeling for the superconducting quantum chip layout, and then conducting derivation and post-processing according to the theory of analytical mechanics. However, as the quantity of qubits in the superconducting quantum chip layout increases, the modeling and post-processing of the superconducting quantum chip layout become more and more complicated, and the solution process becomes very inefficient accordingly. Therefore, there is an urgent need for a solution that can conveniently obtain the coupling strength between target devices in the superconducting quantum chip layout without modeling.

It should be noted that the neighbor qubits (also called adjacent qubits) refer to: for two directly coupled qubits, they can be called neighbor qubits of each other; for example, the qubit 1 and qubit 2 are directly coupled, and the qubit 2 and qubit 3 are directly coupled, and at this time, the qubit 1 and qubit 2 can be called neighbor qubits of each other, for example, the qubit 2 is called the neighbor qubit of qubit 1, or the qubit 1 is called the neighbor qubit of qubit 2; and similarly, the qubit 2 and qubit 3 can also be called neighbor qubits of each other, for example, the qubit 2 is called the neighbor qubit of qubit 3, or the qubit 3 is called the neighbor qubit of qubit 2. In this scenario, the qubit 1 and qubit 3 are indirectly coupled.

Based on this, the solution of the present disclosure proposes a solution for precisely solving the coupling strength between different devices in the superconducting quantum chip layout.

Specifically, FIG. 1 is a first schematic diagram of an implementation flow of a simulation method according to an embodiment of the present disclosure. This method may optionally be applied to a classical computing device, such as a personal computer, a server, a server cluster, and any other electronic device with classical computing capability. Further, this method includes at least a part of the following content. Specifically, as shown in FIG. 1, this method includes the followings.

In step S101, first frequency information of a first target device among at least two devices of a quantum chip layout is obtained through simulation, and second frequency information of a second target device among the at least two devices is obtained through simulation.

Here, it should be noted that the first frequency information and the second frequency information may be obtained in one simulation process or in different simulation processes. For example, the first frequency information is obtained in one simulation process, and the second frequency information is obtained in another simulation process, etc., which is not limited in the solution of the present disclosure.

It should be noted that the layout described in the solution of the present disclosure can describe the geometric shapes of the physical structures in the real quantum chip (or superconducting quantum chip), including but not limited to the shape, area and position of each physical structure on the quantum chip, etc. For example, the quantum chip layout describes the positions of various devices such as qubits, couplers and read cavities, and the connection relationship thereof, etc.

In step S102, a coupling strength between the first target device and the second target device among the at least two devices is obtained based on the first frequency information and the second frequency information.

In this way, the solution of the present disclosure can conveniently obtain the coupling strength between the target devices (such as the first target device and the second target device) in the quantum chip layout without modeling the quantum chip layout, so it is more applicable to the scene where there are a large quantity of qubits in the quantum chip layout.

It should be noted that the first target device and the second target device described in the solution of the present disclosure are any two devices that have a coupling relationship in the quantum chip layout, which is not limited in the solution of the present disclosure.

In a specific example, the quantum chip layout may also specifically be a layout of a superconducting quantum chip. Here, the superconducting quantum chip refers to a quantum chip made of superconducting materials. For example, all components (such as qubits, couplers, etc.) in the superconducting quantum chip are made of superconducting materials.

Further, when the solution of the present disclosure is applied to the superconducting quantum chip layout, the solution of the present disclosure can also be applicable to superconducting quantum chips of any scale. For example, as the quantity of qubits increases, the solution of the present disclosure is still applicable.

In a specific example of the solution of the present disclosure, the first frequency information of the first target device may be obtained in the following way. Specifically, the method further includes: obtaining frequency ranges corresponding to the at least two devices in the quantum chip layout through simulation; this step can be understood as rough simulation. At this time, the quantum chip layout is regarded as a “black box” and introduced into the electromagnetic simulation system, and then a plurality of modes (such as a plurality of frequencies) are selected and input into the electromagnetic simulation system for simulation processing, to obtain the frequency ranges corresponding to at least two devices in the quantum chip layout.

Further, the above step of obtaining the first frequency information of the first target device among the at least two devices of the quantum chip layout through simulation, specifically includes: obtaining the first frequency information of the first target device through simulation, based on a frequency range corresponding to the first target device among the frequency ranges corresponding to the at least two devices. This step can be understood as precise simulation, for example, a specific frequency value is selected from the frequency range corresponding to the first target device, and the specific frequency value is input into the electromagnetic simulation system to obtain the first frequency information of the first target device, thus improving the precision of the simulation result while improving the simulation efficiency.

That is to say, in this example, a plurality of frequencies are firstly selected for rough simulation to obtain the frequency range corresponding to the device of the quantum chip layout, and then the precise simulation is performed based on the frequency range corresponding to the first target device (for example, a specific frequency value is selected from the frequency range corresponding to the first target device) to obtain the first frequency information of the first target device. In this way, a simple, feasible and efficient simulation way is provided, improving the precision of the simulation result on the basis of improving the simulation efficiency.

In a specific example of the solution of the present disclosure, the above step of obtaining the second frequency information of the second target device among the at least two devices through simulation, specifically includes: obtaining the second frequency information of the second target device through simulation, based on a frequency range corresponding to the second target device among the frequency ranges corresponding to the at least two devices. This step can be understood as precise simulation, for example, a specific frequency value is selected from the frequency range corresponding to the second target device, and the specific frequency value is input into the electromagnetic simulation system to obtain the second frequency information of the second target device.

That is to say, in this example, a plurality of frequencies are firstly selected for rough simulation to obtain the frequency range corresponding to the device of the quantum chip layout, and then the precise simulation is performed based on the frequency range corresponding to the second target device (for example, a specific frequency value is selected from the frequency range corresponding to the second target device) to obtain the second frequency information of the second target device. In this way, a simple, feasible and efficient simulation way is provided, improving the precision of the simulation result while improving the simulation efficiency.

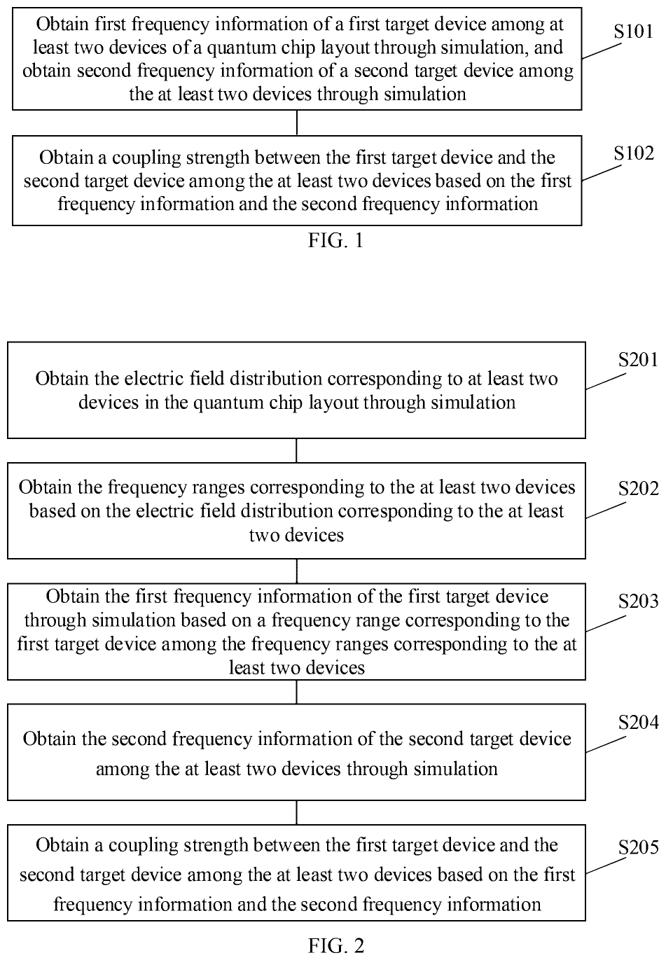

In a specific example of the solution of the present disclosure, a simulation method is also provided. Specifically, FIG. 2 is a second schematic diagram of an implementation flow of the simulation method according to an embodiment of the present disclosure. This method may optionally be applied to a classical computing device, such as a personal computer, a server, a server cluster, and any other electronic device with classical computing capability. Here, it can be understood that the relevant content of the method shown in FIG. 1 described above may also be applied to this example, and the relevant content will not be repeated in this example.

Further, this method includes at least a part of the following content. Specifically, as shown in FIG. 2, this method includes the followings.

In step S201, electric field distribution corresponding to at least two devices in a quantum chip layout is obtained through simulation.

In step S202, frequency ranges corresponding to the at least two devices are obtained based on the electric field distribution corresponding to the at least two devices.

In step S203, first frequency information of the first target device is obtained through simulation based on a frequency range corresponding to the first target device among the frequency ranges corresponding to the at least two devices.

In step S204, second frequency information of the second target device among the at least two devices is obtained through simulation.

For example, in an example, this step S204 may specifically be: obtaining the second frequency information of the second target device through simulation, based on a frequency range corresponding to the second target device among the frequency ranges corresponding to the at least two devices.

In step S205, a coupling strength between the first target device and the second target device among the at least two devices is obtained based on the first frequency information and the second frequency information.

In this way, the solution of the present disclosure provides a solution of specifically obtaining the frequency range corresponding to the device in the quantum chip layout. This solution is simple and feasible, and has strong interpretability and high simulation efficiency; and can conveniently obtain the coupling strength between the target devices (such as the first target device and the second target device) in the quantum chip layout without modeling the quantum chip layout, so it is more applicable to the scene where there are a large quantity of qubits in the quantum chip layout.

In a specific example of the solution of the present disclosure, the simulation processing may be performed in two following ways, specifically including the followings.

In a first simulation way, the coupling type between the first target device and the second target device satisfies a first condition. Further, in a specific example, the coupling type satisfying the first condition is resonant coupling or non-resonant coupling, thus facilitating the targeted simulation processing, and laying a foundation for engineering application and improving the simulation efficiency.

Here, the resonant coupling means that the frequencies of two target devices are identical or very close. Specifically, the difference between the frequencies of the two target devices is less than a preset threshold, and the preset threshold is an empirical value and is a relatively small value. At this time, the two devices can be considered as resonantly coupled.

It can be understood that the solution of the present disclosure does not specifically limit the value of the preset threshold.

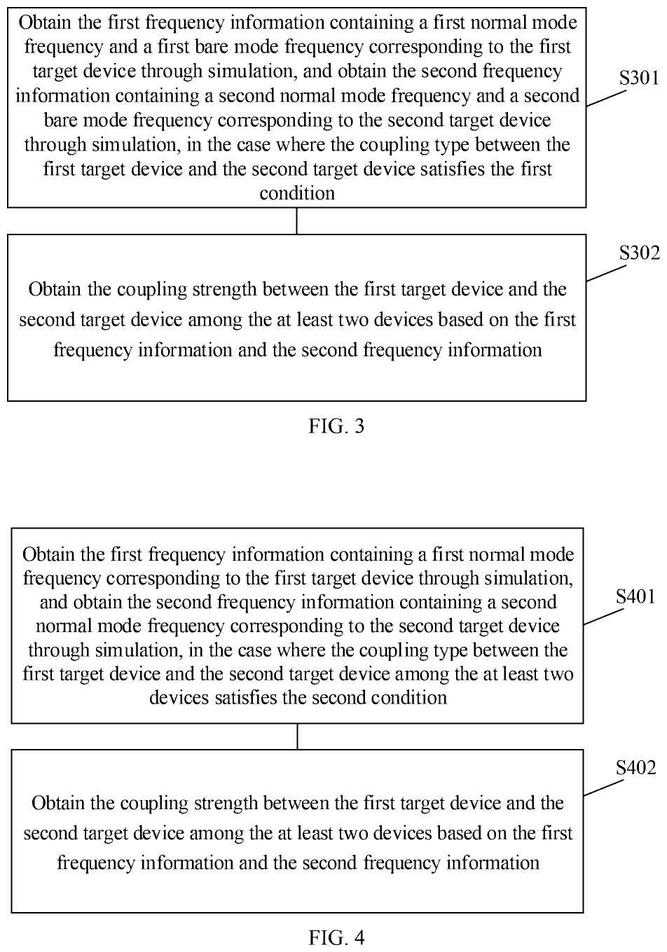

Specifically, FIG. 3 is a third schematic diagram of an implementation flow of a simulation method according to an embodiment of the present disclosure. In this method, the coupling type between the first target device and the second target device satisfies the first condition; and further, this method may optionally be applied to a classical computing device, such as a personal computer, a server, a server cluster, and any other electronic device with classical computing capability. Here, it can be understood that the relevant content of the method shown in FIG. 1 and FIG. 2 described above may also be applied to this example, and the relevant content will not be repeated in this example.

Further, this method includes at least a part of the following content. Specifically, as shown in FIG. 3, this method includes the followings.

In step S301, the first frequency information containing a first normal mode frequency and a first bare mode frequency corresponding to the first target device is obtained through simulation, and the second frequency information containing a second normal mode frequency and a second bare mode frequency corresponding to the second target device is obtained through simulation, in the case where the coupling type between the first target device and the second target device satisfies the first condition.

For example, when the coupling type between the first target device and the second target device is resonant coupling or non-resonant coupling (and further, non-resonant coupling), the first frequency information containing the first normal mode frequency and the first bare mode frequency corresponding to the first target device is obtained through simulation, and the second frequency information containing the second normal mode frequency and the second bare mode frequency corresponding to the second target device is obtained through simulation.

That is to say, when the coupling type between the first target device and the second target device is resonant coupling or non-resonant coupling (and further, non-resonant coupling), the first normal mode frequency and the first bare mode frequency corresponding to the first target device are obtained through simulation; and the second normal mode frequency and the second bare mode frequency corresponding to the second target device are obtained through simulation, thus providing a specific solution of obtaining the frequency information of the target device through simulation under general or special scenarios, and laying a foundation for subsequent calculation to obtain the coupling strength between the first target device and the second target device.

In step S302, the coupling strength between the first target device and the second target device among the at least two devices is obtained based on the first frequency information and the second frequency information.

In this way, the solution of the present disclosure provides a specific solution of obtaining the frequency information of the target device through simulation under general or special scenarios, so the practicability is strong; and moreover, the solution of the present disclosure does not need to understand the physical principles of the quantum chip, and only needs to consider the quantum chip layout as a “black box”, to obtain the first frequency information of the first target device and the second frequency information of the second target device through simulation and thus obtain the coupling strength between the two target devices, so this solution is easy to use.

In a specific example of the solution of the present disclosure, the first normal mode frequency and the first bare mode frequency corresponding to the first target device may be obtained through simulation in the following way.

Specifically, the above step of obtaining the first frequency information containing the first normal mode frequency and the first bare mode frequency corresponding to the first target device through simulation, specifically includes: obtaining the first normal mode frequency of the first target device through simulation; adjusting a physical parameter of a first adjacent device of the first target device in the quantum chip layout, to decouple the first adjacent device of the first target device from the first target device; and obtaining the first bare mode frequency corresponding to the first target device through simulation after the decoupling is completed.

In an example, the first adjacent device of the first target device may specifically include a device directly coupled with the first target device. Further, in another example, the physical parameter may specifically be an equivalent inductance. For example, the inductance value of the equivalent inductance of the device directly coupled with the first target device in the quantum chip layout is adjusted to a larger value (that is, it is larger than the inductance value of the first target device), e.g., 100-500 nH (it can be understood that this value is an empirical value), for the purpose of decoupling the neighbor device of the first target device (that is, the first adjacent devices of the first target device) from the first target device.

It can be understood that the first normal mode frequency and the first bare mode frequency are not obtained in one simulation process. For example, in one simulation process, the first normal mode frequency of the first target device is obtained through simulation; and in another simulation process, the physical parameter of the first adjacent device of the first target device is firstly adjusted to decouple the first adjacent device of the first target device from the first target device, and then the first bare mode frequency corresponding to the first target device is obtained through simulation. Thus, a simple and feasible simulation way to obtain the first bare mode frequency of the first target device is provided, to lay a foundation for subsequent calculation to obtain the coupling strength between the first target device and the second target device.

In a specific example of the solution of the present disclosure, the second normal mode frequency and the second bare mode frequency corresponding to the second target device may be obtained through simulation in the following way.

Specifically, the above step of obtaining the second frequency information containing the second normal mode frequency and the second bare mode frequency corresponding to the second target device through simulation, specifically includes: obtaining the second normal mode frequency of the second target device through simulation; adjusting a physical parameter of a second adjacent device of the second target device in the quantum chip layout, to decouple the second adjacent device of the second target device from the second target device; and obtaining the second bare mode frequency corresponding to the second target device through simulation after the decoupling is completed.

In an example, the second adjacent device of the second target device may specifically include a device directly coupled with the second target device. Further, in another example, the physical parameter may specifically be an equivalent inductance. For example, the inductance value of the equivalent inductance of the device directly coupled with the second target device in the quantum chip layout is adjusted to a larger value (that is, it is larger than the inductance value of the second target device), e.g., 100-500 nH (it can be understood that this value is an empirical value), for the purpose of decoupling the neighbor device of the second target device (that is, the second adjacent devices of the second target device) from the second target device.

It can be understood that the second normal mode frequency and the second bare mode frequency are not obtained in one simulation process. For example, in one simulation process, the second normal mode frequency of the second target device is obtained through simulation; and in another simulation process, the physical parameter of the second adjacent device of the second target device is firstly adjusted to decouple the second adjacent device of the second target device from the second target device, and then the second bare mode frequency corresponding to the second target device is obtained through simulation. Thus, a simple and feasible simulation way to obtain the second bare mode frequency of the second target device is provided, to lay a foundation for subsequent calculation to obtain the coupling strength between the first target device and the second target device.

In a specific example of the solution of the present disclosure, after the first normal mode frequency and the first bare mode frequency corresponding to the first target device and the second normal mode frequency and the second bare mode frequency corresponding to the second target device are obtained through simulation, the coupling strength between the first target device and the second target device may also be obtained in the following way.

Specifically, the above step of obtaining the coupling strength between the first target device and the second target device among the at least two devices based on the first frequency information and the second frequency information, specifically includes: obtaining first simulation precision information based on the first normal mode frequency and the first bare mode frequency corresponding to the first target device and the second normal mode frequency and the second bare mode frequency corresponding to the second target device; and calculating the coupling strength between the first target device and the second target device based on the first normal mode frequency and the first bare mode frequency corresponding to the first target device and the second normal mode frequency and the second bare mode frequency corresponding to the second target device, in the case where the first simulation precision information meets a first precision requirement.

In an example, the first simulation precision information δ is: δ=(\tilde{ω}₁²+\tilde{ω}₂²)−(ω₁²+ω₂²).

Here, \tilde{ω}₁ is the first normal mode frequency of the first target device, \tilde{ω}₂ is the second normal mode frequency of the second target device, ω₁ is the first bare mode frequency of the first target device, and ω₂ is the second bare mode frequency of the second target device.

Further, if δ is less than a first preset value, such as 0.1 GHz², it can be considered that the first precision requirement is satisfied. Further, the coupling strength g between the first target device and the second target device is obtained in the following way:

$$g = \sqrt{\frac{{( {\tilde{ω}}_{1}^{2} - {\tilde{ω}}_{2}^{2} )}^{2} - {( {ω}_{1}^{2} - {ω}_{2}^{2} )}^{2}}{16 {ω}_{1} {ω}_{2}}} .$$

It can be understood that the above is only an example of checking the accuracy. In practical applications, other checking ways may also be used, which is not limited in the solution of the present disclosure.

Further, in another example, if the first simulation precision information does not satisfy the first precision requirement, the simulation precision can be improved, and new first frequency information and second frequency information can be obtained through re-simulation until verification passes.

In this way, a simulation solution that is easy to use, high in accuracy, high in simulation efficiency and strong in applicability is provided, and has important guiding significance for the design, simulation and verification of quantum chips (such as superconducting quantum chips).

In a second simulation way, the coupling type between the first target device and the second target device satisfies a second condition. Further, in a specific example, the coupling type satisfying the second condition is resonant coupling. thus facilitating the targeted simulation processing, and laying a foundation for engineering application and improving the simulation efficiency.

It can be understood that this example provides a method of obtaining the coupling strength between two target devices in a specific scenario. Compared with the method provided in the general scenario above, the method described in this example is simpler and more efficient in the specific scenario (i.e., resonant coupling scenario).

Specifically, FIG. 4 is a fourth schematic diagram of an implementation flow of a simulation method according to an embodiment of the present disclosure. This method may optionally be applied to a classical computing device, such as a personal computer, a server, a server cluster, and any other electronic device with classical computing capability. Here, it can be understood that the relevant content of the method shown in FIG. 1 and FIG. 2 described above may also be applied to this example, and the relevant content will not be repeated in this example.

Further, this method includes at least a part of the following content. Specifically, as shown in FIG. 4, the method includes the followings.

In step S401, the first frequency information containing a first normal mode frequency corresponding to the first target device is obtained through simulation, and the second frequency information containing a second normal mode frequency corresponding to the second target device is obtained through simulation, in the case where the coupling type between the first target device and the second target device among the at least two devices satisfies the second condition.

For example, the coupling type between the first target device and the second target device is resonant coupling, and at this time, the first frequency information containing the first normal mode frequency corresponding to the first target device is obtained through simulation, and the second frequency information containing the second normal mode frequency corresponding to the second target device is obtained through simulation.

That is to say, in the case where the coupling type between the first target device and the second target device is resonant coupling, the first normal mode frequency corresponding to the first target device is obtained through simulation; and the second normal mode frequency corresponding to the second target device is obtained through simulation, thus providing a specific solution of obtaining the frequency information of the target device through simulation under special scenarios, and laying a foundation for subsequent calculation to obtain the coupling strength between the first target device and the second target device.

In step S402, the coupling strength between the first target device and the second target device among the at least two devices is obtained based on the first frequency information and the second frequency information.

In this way, the solution of the present disclosure provides a specific solution of obtaining the frequency information of the target device through simulation under special scenarios, and the simulation efficiency of this example is high compared with the simulation solution under general scenarios; and moreover, the solution of the present disclosure does not need to understand the physical principles of the quantum chip, and only needs to consider the quantum chip layout as a “black box”, to obtain the first frequency information of the first target device and the second frequency information of the second target device through simulation and thus obtain the coupling strength between the two target devices, so this solution is easy to use.

In a specific example of the solution of the present disclosure, after the first normal mode frequency corresponding to the first target device and the second normal mode frequency corresponding to the second target device are obtained through simulation, the coupling strength between the first target device and the second target device may also be obtained in the following way.

Specifically, the above step of obtaining the coupling strength between the first target device and the second target device among the at least two devices based on the first frequency information and the second frequency information, specifically includes: obtaining second simulation precision information based on the first normal mode frequency corresponding to the first target device and the second normal mode frequency corresponding to the second target device; and calculating the coupling strength between the first target device and the second target device based on the first normal mode frequency corresponding to the first target device and the second normal mode frequency corresponding to the second target device, in the case where the second simulation precision information satisfies a second precision requirement.

In an example, the second simulation precision information may be obtained in the following way.

The simulation precision is improved, and it is determined whether the last simulation result satisfies the second precision requirement based on two simulation results; for example, the first normal mode frequency \tilde{ω}₁ corresponding to the first target device and the second normal mode frequency \tilde{ω}₂ corresponding to the second target device are obtained under the first simulation precision; the simulation precision is improved, for example, the first simulation precision is improved to the second simulation precision, and a new first normal mode frequency \tilde{ω}*₁ corresponding to the first target device and a new second normal mode frequency \tilde{ω}*₂ corresponding to the second target device are obtained under the second simulation precision; and then the second simulation precision information δ is obtained based on the new first normal mode frequency \tilde{ω}*₁ and the new second normal mode frequency \tilde{ω}*₂, and the first normal mode frequency \tilde{ω}₁ and the second normal mode frequency \tilde{ω}₂ under the first simulation precision. For example, the second simulation precision information δ is: δ=(\tilde{ω}₁−\tilde{ω}*₁)²+(\tilde{ω}₂+\tilde{ω}*₂)².

Further, if δ is less than a second preset value, it can be considered that the second precision requirement is satisfied. Further, the coupling strength g between the first target device and the second target device is obtained in the following way: g=|\tilde{ω}₁−\tilde{ω}₂|/2.

It can be understood that the above is only an example of checking the accuracy. In practical applications, other checking ways may also be used, which is not limited in the solution of the present disclosure.

Further, in another example, if the second simulation precision information does not satisfy the second precision requirement, the simulation precision may be improved again, and new first frequency information and second frequency information may be obtained through re-simulation again, until verification passes.

In this way, an efficient simulation solution that is easy to use, high in accuracy and applicable to specific scenarios is provided, and has important guiding significance for the design, simulation and verification of quantum chips (such as superconducting quantum chips).

The solution of the present disclosure will be further described in detail below with reference to specific examples; and specifically, the solution of the present disclosure proposes a solution for precisely solving the coupling strength between different devices in a quantum chip layout (such as a superconducting quantum chip layout). Specifically, a method of solving the coupling strength between different devices based on the “Normal mode method” is proposed. Using the solution of the present disclosure, for example, the coupling strength between qubits, the coupling strength between a qubit and a read cavity, etc. can be solved. It is worth emphasizing that the solution of the present disclosure does not require modeling or complex post-processing, and is applicable to the resonant coupling interval and dispersive coupling interval.

Further, compared with the existing solutions in the industry, the solution of the present disclosure can simulate the quantum chip layout as a “black box”, so the solution of the present disclosure can verify the results of the existing methods in the industry, and it can be seen from verification that the simulation result of the solution of the present disclosure is more accurate.

Therefore, the solution of the present disclosure has important guiding significance for the design, simulation and verification of quantum chips (such as superconducting quantum chips).

The solution of the present disclosure will be described below from three aspects. The part I introduces the background knowledge of the quantum chip layout (such as the superconducting quantum chip layout) and clarifies the problems that the solution of the present disclosure aims to solve; the part II discusses the solution of solving the coupling strength between different devices in the quantum chip layout proposed in the solution of the present disclosure, where firstly the specific steps for the general coupling situation are given, and secondly a simplified version of the solution is also given for the resonance interval; and the part III applies the solution of the present disclosure to the superconducting quantum chips common in the industry with two different structures and two different coupling intervals, in order to demonstrate the effectiveness and universality of the solution of the present disclosure.

All parts are described in detail below, specifically including the followings.

### Part I

This part mainly introduces the background knowledge of quantum chip layout (such as superconducting quantum chip layout) and the necessity of solving the coupling strength between different devices.

(1) Background Knowledge

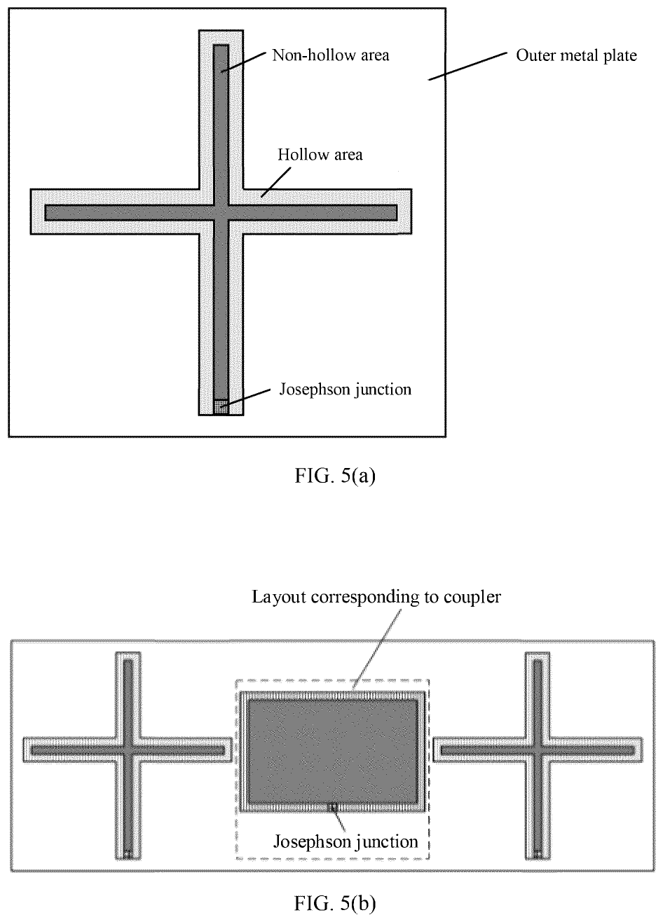

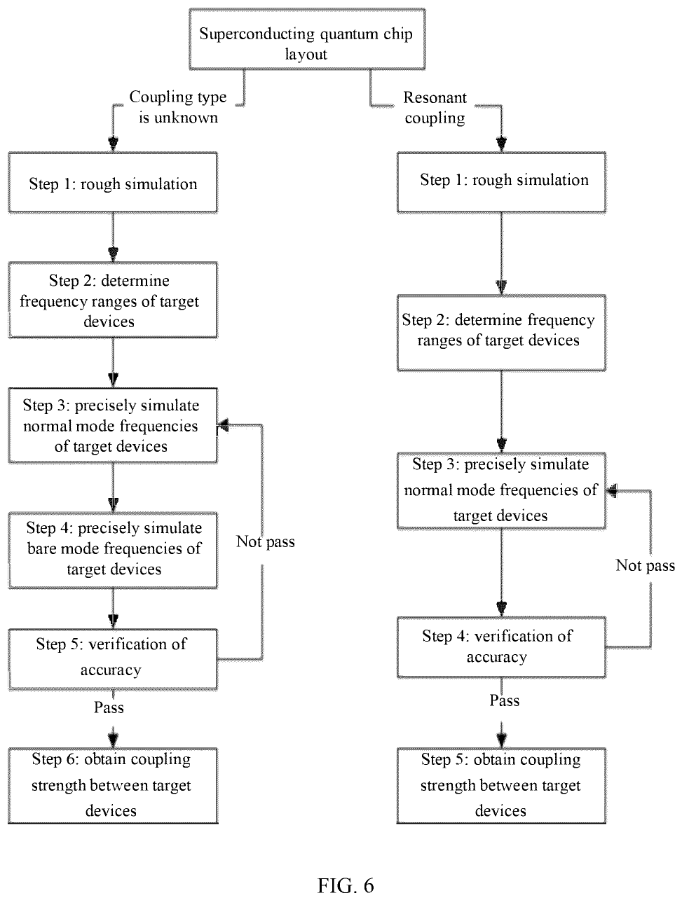

Similar to classical chips, the quantum chip (such as superconducting quantum chip) also requires a complete layout before formal production and processing. The layout contains information about all core components (such as qubits, couplers, control lines, read lines, etc.) of the quantum chip. Among the core devices, one of the most important devices is a qubit and in the actual layout, the qubit may usually be composed of a coplanar capacitor and a Josephson junction. In practice, firstly a substrate (usually realized by silicon or sapphire) is designed, then a layer of aluminum film is coated on the substrate, the self-capacitance of the qubit is formed by etching different shapes on the aluminum film, and finally the nonlinear Josephson junction will be designed between two metal plates. As shown in FIG. 5(a), it is a schematic structural diagram of a single-qubit quantum chip layout, including: a cross-shaped figure, including a hollow area and a non-hollow area, where the hollow area is obtained by etching away a part of the metal plate; an outer metal plate for grounding; and a Josephson junction placed between the bottom of the cross-shaped figure and the outer metal plate.

Here, the cross-shaped figure, the outer metal plate and the Josephson junction are coplanar, that is, belong to a coplanar structure. Here, the Josephson junction may be represented by an equivalent inductance in actual electromagnetic simulation.

Further, as shown in FIG. 5(b), it presents a schematic diagram of a quantum chip layout including a “Qubit-Coupler-Qubit” (that is, two-qubit) structure, where the coupler is arranged between two adjacent qubits and is configured to couple the two adjacent qubits. Here, the structure of the qubit in the two-qubit quantum chip layout can refer to the above description, and will not be repeated here. It can be understood that the two-qubit quantum chip layout shown in FIG. 5(b) is only an exemplary illustration, and is not used to limit the solution of the present disclosure. In practical applications, other structures can also be used, which are not limited in the solution of the present disclosure.

(2) Clarify the Problem that the Solution of the Present Disclosure Aims to Solve

Once the quantum chip layout including multiple devices is given, the problem to be solved by the solution of the present disclosure is specifically how to accurately estimate and determine the coupling strength between different devices.

It should be noted that the solution of the present disclosure can simulate the quantum chip layout as a “black box”, so there is no limitation on the specific structure of the quantum chip layout. In other words, any quantum chip layout can be simulated by the method described in the solution of the present disclosure, and the coupling strength between two target devices can be obtained.

### Part II

In a quantum chip layout (such as a superconducting quantum chip layout), the coupling types between different devices can be simply divided into three categories.

(1) Resonant coupling, that is, the frequencies of two devices are identical or very close. Specifically, the difference between the frequencies of the two devices is less than a preset threshold, and at this time, the two devices can be considered to be resonantly coupled. Here, the preset threshold is an empirical value, which is not specifically limited in the solution of the present application.

Common application scenarios include: coupling between qubits coupled arbitrarily (such as neighbor coupling or non-neighbor coupling), and coupling between two qubits in a “Qubit-Coupler-Qubit” structure.

(2) Dispersive coupling, that is, the coupling strength between two devices is much less than the frequency difference between them. Common application scenarios include: coupling between a qubit and a read cavity, and coupling between a qubit and a coupler in a “Qubit-Coupler-Qubit” structure.

(3) Other types of coupling, that is, other types of coupling except resonant coupling and dispersive coupling.

It should be noted that the solution of the present disclosure is applicable to all of the above three different types of coupling. Specifically, the solution of the present disclosure firstly provides a general solution for any coupling type and explains the specific steps in detail; and secondly further provides a simplified solution for the resonant coupling situation, which can efficiently determine the coupling strength of two devices that are resonantly coupled through the simple steps and method.

In a first simulation way, as shown in FIG. 6, when the coupling type between devices in the quantum chip layout is not clear or belongs to non-resonant coupling (such as dispersive coupling, other coupling, etc.), the specific steps of simulating the coupling strength of two target devices (such as the first target device and the second target device) include the followings.

Step 1: rough simulation. Firstly, the quantum chip layout is imported as a “black box” into an electromagnetic simulation system (such as electromagnetic simulation software); and secondly, multiple modes (that is, multiple frequencies) are selected and input to the electromagnetic simulation system for low-precision simulation.

In practical applications, 5 or 10 frequencies may be selected according to the actual situation and input to the electromagnetic simulation system. Moreover, in the rough simulation step, in order to improve the simulation efficiency, the simulation precision may also be set to be lower, for example, set to 0.1%.

It can be understood that the simulation precision may be set based on actual simulation needs, which is not specifically limited in the solution of the present disclosure.

Step 2: determine the frequency ranges of two target devices. According to the simulation result obtained in step 1, the approximate frequency ranges of the first target device and the second target device are determined.

Specifically, the low-precision simulation in step 1 can obtain the electric field distribution corresponding to multiple devices in the quantum chip layout, and the frequency ranges corresponding to the multiple devices in the quantum chip layout are identified based on the electric field distribution corresponding to the multiple devices. Further, an approximate frequency range of the first target device and an approximate frequency range of the second target device are identified from the obtained frequency ranges corresponding to the multiple devices.

In practical applications, the frequency range of the first target device is not continuous frequency values, but discrete, that is, the obtained frequency range of the first target device includes multiple frequencies. Similarly, the frequency range of the second target device is not continuous frequency values, but discrete, that is, the obtained frequency range of the second target device includes multiple frequencies.

It should be noted that, in practical applications, if there is spurious mode (that is, spurious frequency) (such as chip mode or structure mode) in the quantum chip layout to make it difficult to identify the frequency range of the device, then the quantum chip layout needs to be adjusted, for example, the geometry dimensions of the vacuum layer in the quantum chip layout will be adjusted to keep the device mode as far away from the parasitic mode as possible, so that the mode (such as frequency) of the target device can be clearly identified in a specific frequency interval.

Step 3: precisely simulate the normal mode frequencies of the two target devices.

Here, the precise simulation is performed according to the device modes of the two target devices (for example, the frequencies of the target devices) determined in step 2.

Here, in this step, in order to ensure the precision of the simulation result, only one mode may be selected for simulation. For example, a frequency is selected from the frequency range of the first target device and input into the electromagnetic simulation software to obtain the first normal mode frequency \tilde{ω}₁ of the first target device; and similarly, a frequency is selected from the frequency range of the second target device and input into the electromagnetic simulation software to obtain the second normal mode frequency \tilde{ω}₂ of the second target device. In this way, the normal mode frequencies of the two target devices concerned are simulated sequentially.

Step 4: precisely simulate the bare mode frequencies of the target devices.

Here, the inductance values of all adjacent devices of the first target device are adjusted to a larger value (for example, 100-500 nH), for the purpose of decoupling the adjacent devices of the first target device from the first target device. The precise simulation is performed after the setting, consistent with step 3. A frequency is selected from the frequency range of the first target device and input into the electromagnetic simulation software to obtain the first bare mode frequency ω₁ of the first target device. Similarly, the inductance values of all adjacent devices of the second target device are adjusted to a larger value (for example, 100-500 nH), for the purpose of decoupling the adjacent devices of the second target device from the second target device. The precise simulation is performed after the setting, consistent with step 3. A frequency is selected from the frequency range of the second target device and input into the electromagnetic simulation software to obtain the second bare mode frequency ω₂ of the second target device.

It should be noted that the simulation result obtained by this simulation is an approximate bare mode frequency of the device. Further, in practical applications, the simulation precision and convergence precision in step 3 and step 4 need to be consistent.

Step 5: verification of accuracy.

It is checked whether the simulation precision in step 3 and step 4 reaches the standard. Specifically, the first normal mode frequency \tilde{ω}₁, the second normal mode frequency \tilde{ω}₂, the first bare mode frequency ω₁ and the second bare mode frequency ω₂ obtained in step 3 and step 4 are substituted into the following formula to obtain the first simulation precision information δ: δ=(\tilde{ω}₁²+\tilde{ω}₂²)−(ω₁²+ω₂²).

If δ<0.1 GHz², the verification passes, and step 6 is performed; otherwise, the process returns to step 3, where the simulation precision is improved (for example, the simulation precision is set to 0.05%) for re-simulation, and the obtained new first normal mode frequency \tilde{ω}₁, new second normal mode frequency \tilde{ω}₂, new first bare mode frequency ω₁ and new second bare mode frequency ω₂ are substituted into the above formula until the verification passes.

It should be noted that the accuracy verification formula is only a specific example in this example. In practical applications, there may be other verification methods, which are not limited in the solution of the present disclosure.

Step 6: obtain the coupling strength. Based on the simulation result verified in step 5, the coupling strength g between the two target devices, that is, the first target device and the second target device, may be obtained by the following formula:

$$g = \sqrt{\frac{{( {\tilde{ω}}_{1}^{2} - {\tilde{ω}}_{2}^{2} )}^{2} - {( {ω}_{1}^{2} - {ω}_{2}^{2} )}^{2}}{16 {ω}_{1} {ω}_{2}}} .$$

In this way, when the coupling type between the two devices to be simulated in the quantum chip layout is not clear, the coupling strength of them can be obtained by simulation based on the above process, which is obviously both universal and practical.

In a second simulation way, the resonant coupling may occur in the quantum chip design. For example, there is usually resonant coupling between two qubits with exactly the same configuration, or between two devices with the same frequency. Based on this, as a special case of aforementioned coupling of any form, the above simulation process can be simplified, so as to improve the simulation efficiency. Specifically, as shown in FIG. 6, when the coupling type between devices in the quantum chip layout is resonant coupling, the specific steps of simulating the coupling strength of two target devices (such as the first target device and the second target device) include the followings.

Step 1: rough simulation. Firstly, the quantum chip layout is imported as a “black box” into an electromagnetic simulation system (such as electromagnetic simulation software); and secondly, multiple modes (that is, multiple frequencies) are selected and input to the electromagnetic simulation system for low-precision simulation.

In practical applications, 5 or 10 frequencies may be selected according to the actual situation and input to the electromagnetic simulation system. Moreover, in the rough simulation step, in order to improve the simulation efficiency, the simulation precision may also be set to be lower, for example, set to 0.1%.

It can be understood that the simulation precision may be set based on actual simulation needs, which is not specifically limited in the solution of the present disclosure.

Step 2: determine the frequency ranges of two target devices. According to the simulation result obtained in step 1, the approximate frequency ranges of the first target device and the second target device are determined.

Specifically, the low-precision simulation in step 1 can obtain the electric field distribution corresponding to multiple devices in the quantum chip layout, and the frequency ranges corresponding to the multiple devices in the quantum chip layout are identified based on the electric field distribution corresponding to the multiple devices. Further, an approximate frequency range of the first target device and an approximate frequency range of the second target device are identified from the obtained frequency ranges corresponding to the multiple devices.

In practical applications, the frequency range of the first target device is not continuous frequency values, but discrete, that is, the obtained frequency range of the first target device includes multiple frequencies. Similarly, the frequency range of the second target device is not continuous frequency values, but discrete, that is, the obtained frequency range of the second target device includes multiple frequencies.

It should be noted that, in practical applications, if there is spurious mode (that is, spurious frequency) (such as chip mode or structure mode) in the quantum chip layout to make it difficult to identify the frequency range of the device, then the quantum chip layout needs to be adjusted, for example, the geometry dimensions of the vacuum layer in the quantum chip layout will be adjusted to keep the device mode as far away from the parasitic mode as possible, so that the mode (such as frequency) of the target device can be clearly identified in a specific frequency interval.

Step 3: precisely simulate the normal mode frequencies of the two target devices.

Here, the precise simulation is performed according to the device modes of the two target devices (for example, the frequencies of the target devices) determined in step 2.

Here, in this step, in order to ensure the precision of the simulation result, only one mode may be selected for simulation. For example, a frequency is selected from the frequency range of the first target device and input into the electromagnetic simulation software, and at the same time, a frequency is selected from the frequency range of the second target device and input into the electromagnetic simulation software, thereby obtaining the first normal mode frequency \tilde{ω}₁ of the first target device and the second normal mode frequency \tilde{ω}₂ of the second target device in one simulation process. In this way, the normal mode frequencies of the two target devices concerned are simulated sequentially.

It can be understood that the normal mode frequencies of the two target devices are close, so the first normal mode frequency of the first target device and the second normal mode frequency of the second target device may be obtained by one simulation in this example.

Step 4: verification of accuracy.

It is checked whether the simulation precision in step 3 reaches the standard. Specifically, the simulation precision in step 3 is improved (for example, the simulation precision is set to 0.05%), and step 3 is repeated to obtain a new first normal mode frequency \tilde{ω}₁ and a new second normal mode frequency \tilde{ω}₂; at this time, the second simulation precision information is obtained based on the new simulation result and the historical result, and then it is determined whether the simulation precision reaches the standard based on the second simulation precision information; for example, if the new simulation result is consistent with the historical simulation result obtained in step 3, for example, the difference thereof is less than a threshold, then it can be considered that they are consistent, and then step 5 is performed; otherwise, the simulation precision in step 3 continues to be improved, and step 3 is repeated until the simulation precision reaches the standard.

It should be noted that the accuracy verification formula is only a specific example in this example. In practical applications, there may be other verification methods, which are not limited in the solution of the present disclosure.

Step 5: obtain the coupling strength between target devices. Based on the simulation result verified in step 4, the coupling strength between the two target devices, that is, the coupling strength g between the first target device and the second target device, may be obtained by the following formula: g=|\tilde{ω}₁−\tilde{ω}₂|/2.

In this way, when the coupling type between the two devices to be simulated in the quantum chip layout is resonant coupling, the coupling strength of them can be obtained by simulation based on the above process, and this method is simple and has high simulation efficiency.

### Part III

Specifically, in order to verify the application effect of the solution of the present disclosure, it is applied to two superconducting quantum chip layouts of different structures. In addition, two cases of dispersive coupling and resonant coupling between two target devices are selected respectively. Subsequently, the simulation result of the equivalent circuit method commonly used in the industry is compared with that of the solution of the present disclosure to verify the effectiveness and universality of the solution of the present disclosure.

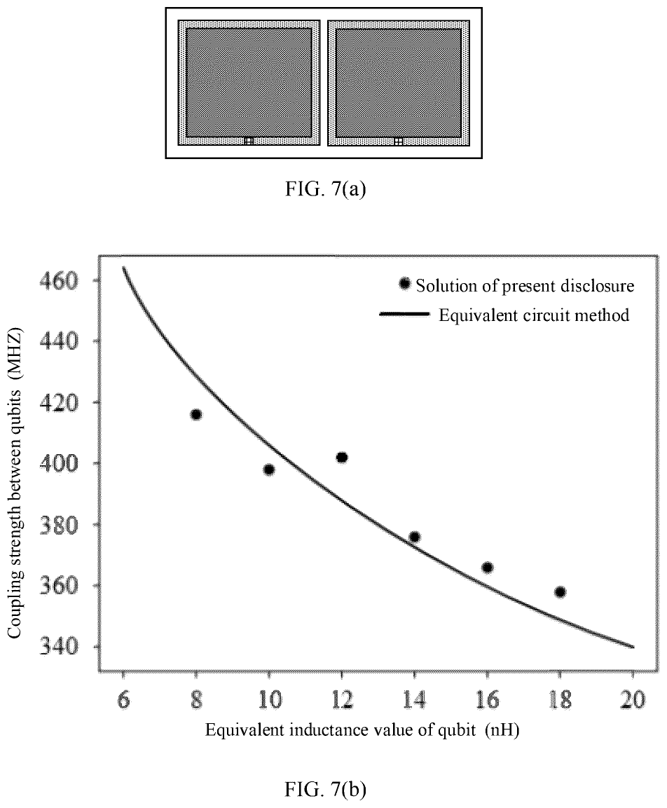

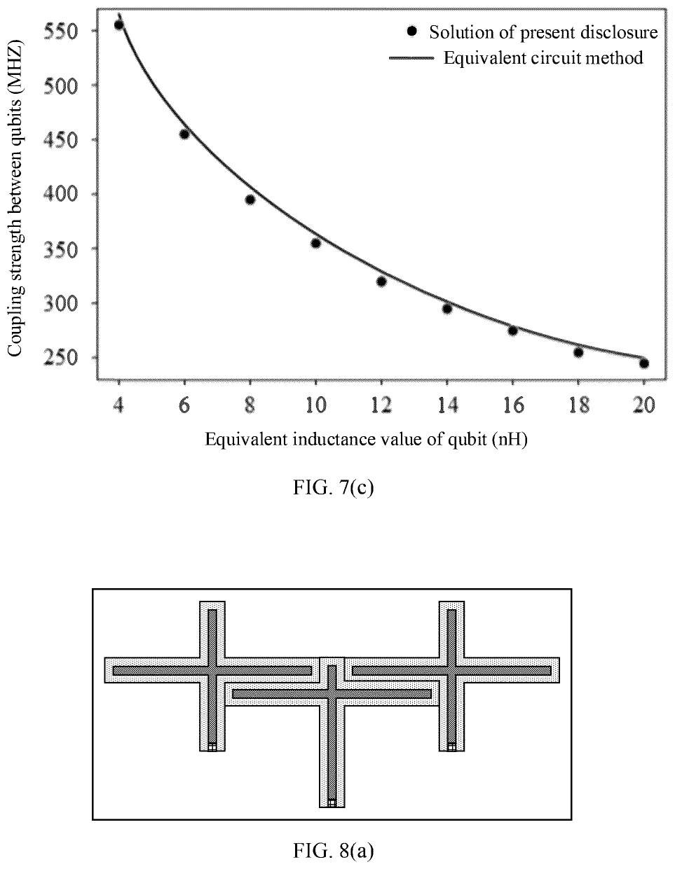

Example 1: As shown in FIG. 7(a), it is applied to a quantum chip layout containing two qubits. At this time, the two qubits can become adjacent qubits to each other, and the two qubits are dispersively coupled.

Specifically, as shown in FIG. 7(a), the inductance value of the left qubit is fixed at 6 nH, and the inductance values of the right qubit are respectively set to 8 nH, 10 nH, 12 nH, 14 nH, 16 nH and 18 nH; and then the solution of the present disclosure is used to solve the coupling strength of the two qubits.

Here, in order to verify the correctness of the result of the solution of the present disclosure, the electromagnetic simulation is performed on the same quantum chip layout to obtain the self-capacitance of each qubit and the mutual capacitance between the two qubits, and the coupling strength between the two qubits is obtained through the equivalent circuit method.

Specifically, as shown in FIG. 7(b), the variation characteristic of the coupling strength between two adjacent qubits with the inductance value of the right qubit is given. Here, the horizontal axis corresponds to the inductance value of the right qubit. It can be seen from FIG. 7(b) that the simulation result obtained by the solution of the present disclosure is in good agreement with the simulation result of the equivalent circuit under different inductance values.

Example 2: As shown in FIG. 7(a), it is applied to a quantum chip layout containing two qubits. At this time, the two qubits can be called adjacent qubits to each other, and the two qubits are resonantly coupled.

Specifically, as shown in FIG. 7(a), the inductance values of the left and right qubits are set to realize resonant coupling between them. In this example, the inductance values of the left and right qubits are selected as 4 nH, 6 nH, 8 nH, 10 nH, 12 nH, 14 nH, 16 nH and 18 nH; and then the solution of the present disclosure is used to solve the coupling strength of the two qubits.

Here, in order to verify the correctness of the result of the solution of the present disclosure, the electromagnetic simulation is performed on the same quantum chip layout to obtain the self-capacitance of each qubit and the mutual capacitance between the qubits, and the coupling strength between the two qubits is obtained through the equivalent circuit method.

Specifically, as shown in FIG. 7(c), the variation characteristic of the coupling strength between two adjacent qubits with the inductance values of the qubits is given, where the inductance values of the qubits on the left and right sides are set to the same value, and the horizontal axis corresponds to the inductance value of the qubit. It can be seen from FIG. 7(c) that the simulation result obtained by the solution of the present disclosure is in good agreement with the simulation result of the equivalent circuit under different inductance values.

Example 3: As shown in FIG. 8(a), in order to demonstrate the universality of the solution of the present disclosure, the solution of the present disclosure is applied to the “Qubit-Coupler-Qubit” structure that has received much attention in the superconducting quantum chip. At this time, the two qubits can also become adjacent qubits to each other, and the two qubits are resonantly coupled.

Here, a core requirement in this structure is to solve the equivalent coupling strength between the left and right qubits. The equivalent circuit solution commonly used in the industry needs to firstly simulate the self-capacitance of each device and the mutual capacitance between any two devices in FIG. 8(a), then conduct the relatively complicated theoretical derivation, and finally obtain the equivalent coupling strength between the left and right qubits approximately. Obviously, the existing solution is relatively complicated, and the simulation efficiency is reduced.

Further, as shown in FIG. 8(b), it shows the variation characteristic of the equivalent coupling strength between qubits with the equivalent inductance value of the intermediate coupler. Here, the inductance values of the left and right qubits are the same, and both 10 nH; and obviously, as shown in FIG. 8(b), the simulation result obtained by the solution of the present disclosure is very close to that obtained by the equivalent circuit solution. Here, the small numerical deviation is due to the neglect of the inductive coupling between qubits in modeling the equivalent circuit. This fully demonstrates that the solution of the present disclosure is also applicable to the more complicated “Qubit-Coupler-Qubit” structure.

In this example, for the sake of convenience, only the capacitive coupling between qubits is considered when modeling the equivalent circuit of the quantum chip layout, while the inductive coupling between them is ignored.

Obviously, compared with the existing solutions in the industry, the solution of the present disclosure has the following advantages.

(1) Simple and easy to use. The threshold for using the method proposed in the solution of the present disclosure is very low. There is no need to understand the physical principle of the quantum chip, and the quantum chip layout is just treated as a “black box” to obtain the coupling strength between two target devices through simulation.

(2) High precision. Compared with the equivalent circuit commonly used in the industry, the solution of the present disclosure does not require modeling and only needs to treat the quantum chip layout as a “black box”, so the problem of incomplete or imprecise simulation result due to imprecise modeling in the quantum chip layout is effectively avoided, and the obtained simulation result is more complete and precise. Moreover, benefiting from a more complete consideration of the quantum chip layout, the solution of the present disclosure can provide the industry with a more precise characteristic parameter analysis and verification method, which has important guiding significance for the design, simulation and verification of quantum chips (such as superconducting quantum chips).

(3) Strong scalability. The solution of the present disclosure is not only applicable to the scene where two target devices are in the resonant coupling interval and the dispersion interval, but also applicable to the more general scene of any coupling interval. Further, the solution of the present disclosure is not only applicable to the coupling between qubits, but also can be extended to the coupling between a qubit and a resonant cavity; and furthermore, the solution of the present disclosure is not only applicable to adjacent coupled devices, but also applicable to next-nearest devices or devices with a relatively remote distance.

(4) Wide practicability. The solution of the present disclosure not only provides a solution for solving the coupling strength between two target devices, but also can be used to verify the final quantum chip layout. Especially when the quantity of qubits in the quantum chip layout gradually increases, the solution of the present disclosure is still applicable. This provides effective technical support for subsequent simulation, analysis and verification of the chip containing a large scale of qubits.

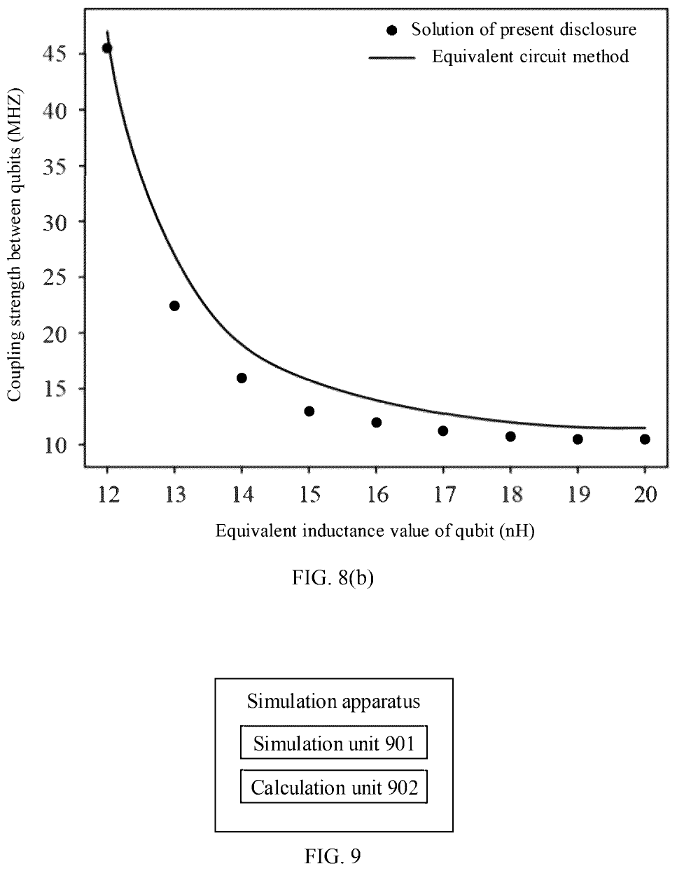

The solution of the present disclosure further provides a simulation apparatus, as shown in FIG. 9, including: a simulation unit 901 configured to obtain first frequency information of a first target device among at least two devices of a quantum chip layout through simulation, and obtain second frequency information of a second target device among the at least two devices through simulation; and a calculation unit 902 configured to obtain a coupling strength between the first target device and the second target device among the at least two devices based on the first frequency information and the second frequency information.

In a specific example of the solution of the present disclosure, the simulation unit 901 is further configured to: obtain frequency ranges corresponding to the at least two devices in the quantum chip layout through simulation; and obtain the first frequency information of the first target device through simulation, based on a frequency range corresponding to the first target device among the frequency ranges corresponding to the at least two devices.

In a specific example of the solution of the present disclosure, the simulation unit 901 is specifically configured to: obtain the second frequency information of the second target device through simulation, based on a frequency range corresponding to the second target device among the frequency ranges corresponding to the at least two devices.

In a specific example of the solution of the present disclosure, the simulation unit 901 is specifically configured to: obtain electric field distribution corresponding to the at least two devices in the quantum chip layout through simulation; and obtain the frequency ranges corresponding to the at least two devices based on the electric field distribution corresponding to the at least two devices.

In a specific example of the solution of the present disclosure, the simulation unit 901 is specifically configured to: obtain the first frequency information containing a first normal mode frequency and a first bare mode frequency corresponding to the first target device through simulation, and obtain the second frequency information containing a second normal mode frequency and a second bare mode frequency corresponding to the second target device through simulation, in the case where a coupling type between the first target device and the second target device satisfies a first condition.

In a specific example of the solution of the present disclosure, the simulation unit 901 is specifically configured to: obtain the first normal mode frequency of the first target device through simulation; adjust a physical parameter of a first adjacent device of the first target device in the quantum chip layout, to decouple the first adjacent device of the first target device from the first target device; and obtain the first bare mode frequency corresponding to the first target device through simulation after the decoupling is completed.

In a specific example of the solution of the present disclosure, the simulation unit 901 is specifically configured to: obtain the second normal mode frequency of the second target device through simulation; adjust a physical parameter of a second adjacent device of the second target device in the quantum chip layout, to decouple the second adjacent device of the second target device from the second target device; and obtain the second bare mode frequency corresponding to the second target device through simulation after the decoupling is completed.

In a specific example of the solution of the present disclosure, the calculation unit 902 is specifically configured to: obtain first simulation precision information based on the first normal mode frequency and the first bare mode frequency corresponding to the first target device and the second normal mode frequency and the second bare mode frequency corresponding to the second target device; and calculate the coupling strength between the first target device and the second target device based on the first normal mode frequency and the first bare mode frequency corresponding to the first target device and the second normal mode frequency and the second bare mode frequency corresponding to the second target device, in the case where the first simulation precision information satisfies a first precision requirement.

In a specific example of the solution of the present disclosure, the coupling type satisfying the first condition is resonant coupling or non-resonant coupling.

In a specific example of the solution of the present disclosure, the simulation unit 901 is specifically configured to: obtain the first frequency information containing a first normal mode frequency corresponding to the first target device through simulation, and obtain the second frequency information containing a second normal mode frequency corresponding to the second target device through simulation, in the case where a coupling type between the first target device and the second target device among the at least two devices satisfies a second condition.

In a specific example of the solution of the present disclosure, the calculation unit 902 is specifically configured to: obtain second simulation precision information based on the first normal mode frequency corresponding to the first target device and the second normal mode frequency corresponding to the second target device; and calculate the coupling strength between the first target device and the second target device based on the first normal mode frequency corresponding to the first target device and the second normal mode frequency corresponding to the second target device, in the case where the second simulation precision information satisfies a second precision requirement.

In a specific example of the solution of the present disclosure, the coupling type satisfying the second condition is resonant coupling.

For the description of specific functions and examples of the units of the apparatus of the embodiment of the present disclosure, reference may be made to the relevant description of the corresponding steps in the above-mentioned method embodiments, and details are not repeated here.

In the technical solution of the present disclosure, the acquisition, storage and application of the user's personal information involved are in compliance with relevant laws and regulations, and do not violate public order and good customs.

According to the embodiments of the present disclosure, the present disclosure also provides an electronic device, a readable storage medium and a computer program product.

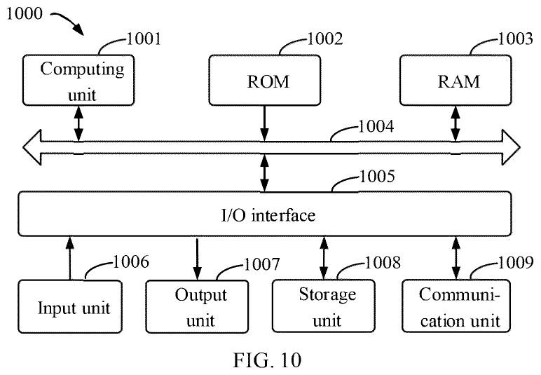

FIG. 10 shows a schematic block diagram of an exemplary electronic device 1000 that may be used to implement the embodiments of the present disclosure. The electronic device is intended to represent various forms of digital computers, such as a laptop, a desktop, a workstation, a personal digital assistant, a server, a blade server, a mainframe computer, and other suitable computers. The electronic device may also represent various forms of mobile devices, such as a personal digital processing, a cellular phone, a smart phone, a wearable device and other similar computing devices. The components shown herein, their connections and relationships, and their functions are merely examples, and are not intended to limit the implementation of the present disclosure described and/or required herein.

As shown in FIG. 10, the device 1000 includes a computing unit 1001 that may perform various appropriate actions and processes according to a computer program stored in a Read-Only Memory (ROM) 1002 or a computer program loaded from a storage unit 1008 into a Random Access Memory (RAM) 1003. Various programs and data required for an operation of device 1000 may also be stored in the RAM 1003. The computing unit 1001, the ROM 1002 and the RAM 1003 are connected to each other through a bus 1004. The input/output (I/O) interface 1005 is also connected to the bus 1004.

A plurality of components in the device 1000 are connected to the I/O interface 1005, and include an input unit 1006 such as a keyboard, a mouse, or the like; an output unit 1007 such as various types of displays, speakers, or the like; the storage unit 1008 such as a magnetic disk, an optical disk, or the like; and a communication unit 1009 such as a network card, a modem, a wireless communication transceiver, or the like. The communication unit 1009 allows the device 1000 to exchange information/data with other devices through a computer network such as the Internet and/or various telecommunication networks.

The computing unit 1001 may be various general-purpose and/or special-purpose processing components with processing and computing capabilities. Some examples of the computing unit 1001 include, but are not limited to, a Central Processing Unit (CPU), a Graphics Processing Unit (GPU), various dedicated Artificial Intelligence (AI) computing chips, various computing units that run machine learning model algorithms, a Digital Signal Processor (DSP), and any appropriate processors, controllers, microcontrollers, or the like. The computing unit 1001 performs various methods and processing described above, such as the simulation method. For example, in some implementations, the simulation method may be implemented as a computer software program tangibly contained in a computer-readable medium, such as the storage unit 1008. In some implementations, a part or all of the computer program may be loaded and/or installed on the device 1000 via the ROM 1002 and/or the communication unit 1009. When the computer program is loaded into the RAM 1003 and executed by the computing unit 1001, one or more steps of the simulation method described above may be performed. Alternatively, in other implementations, the computing unit 1001 may be configured to perform the simulation method by any other suitable means (e.g., by means of firmware).

Various implementations of the system and technologies described above herein may be implemented in a digital electronic circuit system, an integrated circuit system, a Field Programmable Gate Array (FPGA), an Application Specific Integrated Circuit (ASIC), Application Specific Standard Parts (ASSP), a System on Chip (SOC), a Complex Programmable Logic Device (CPLD), a computer hardware, firmware, software, and/or a combination thereof. These various implementations may be implemented in one or more computer programs, and the one or more computer programs may be executed and/or interpreted on a programmable system including at least one programmable processor. The programmable processor may be a special-purpose or general-purpose programmable processor, may receive data and instructions from a storage system, at least one input device, and at least one output device, and transmit the data and the instructions to the storage system, the at least one input device, and the at least one output device.

The program code for implementing the method of the present disclosure may be written in any combination of one or more programming languages. The program code may be provided to a processor or controller of a general-purpose computer, a special-purpose computer or other programmable data processing devices, which enables the program code, when executed by the processor or controller, to cause the function/operation specified in the flowchart and/or block diagram to be implemented. The program code may be completely executed on a machine, partially executed on the machine, partially executed on the machine as a separate software package and partially executed on a remote machine, or completely executed on the remote machine or a server.

In the context of the present disclosure, a machine-readable medium may be a tangible medium, which may contain or store a procedure for use by or in connection with an instruction execution system, device or apparatus. The machine-readable medium may be a machine-readable signal medium or a machine-readable storage medium. The machine-readable medium may include, but is not limited to, an electronic, magnetic, optical, electromagnetic, infrared or semiconductor system, device or apparatus, or any suitable combination thereof. More specific examples of the machine-readable storage medium may include electrical connections based on one or more lines, a portable computer disk, a hard disk, a Random Access Memory (RAM), a Read-Only Memory (ROM), an Erasable Programmable Read-Only Memory (EPROM or a flash memory), an optical fiber, a portable Compact Disc Read-Only Memory (CD-ROM), an optical storage device, a magnetic storage device, or any suitable combination thereof.

In order to provide interaction with a user, the system and technologies described herein may be implemented on a computer that has: a display apparatus (e.g., a cathode ray tube (CRT) or a Liquid Crystal Display (LCD) monitor) for displaying information to the user; and a keyboard and a pointing device (e.g., a mouse or a trackball) through which the user may provide input to the computer. Other types of devices may also be used to provide interaction with the user. For example, feedback provided to the user may be any form of sensory feedback (e.g., visual feedback, auditory feedback, or tactile feedback), and the input from the user may be received in any form (including an acoustic input, a voice input, or a tactile input).

The system and technologies described herein may be implemented in a computing system (which serves as, for example, a data server) including a back-end component, or in a computing system (which serves as, for example, an application server) including a middleware, or in a computing system including a front-end component (e.g., a user computer with a graphical user interface or web browser through which the user may interact with the implementation of the system and technologies described herein), or in a computing system including any combination of the back-end component, the middleware component, or the front-end component. The components of the system may be connected to each other through any form or kind of digital data communication (e.g., a communication network). Examples of the communication network include a Local Area Network (LAN), a Wide Area Network (WAN), and the Internet.

A computer system may include a client and a server. The client and server are generally far away from each other and usually interact with each other through a communication network. A relationship between the client and the server is generated by computer programs running on corresponding computers and having a client-server relationship with each other. The server may be a cloud server, a distributed system server, or a blockchain server.

It should be understood that, the steps may be reordered, added or removed by using the various forms of the flows described above. For example, the steps recorded in the present disclosure can be performed in parallel, in sequence, or in different orders, as long as a desired result of the technical solution disclosed in the present disclosure can be realized, which is not limited herein.

The foregoing specific implementations do not constitute a limitation on the protection scope of the present disclosure. Those having ordinary skill in the art should understand that, various modifications, combinations, sub-combinations and substitutions may be made according to a design requirement and other factors. Any modification, equivalent replacement, improvement or the like made within the spirit and principle of the present disclosure shall be included in the protection scope of the present disclosure.

What is claimed is:

1. A simulation method, comprising:
obtaining first frequency information of a first target device among at least two devices of a quantum chip layout through simulation;
obtaining second frequency information of a second target device among the at least two devices through simulation; and
obtaining a coupling strength between the first target device and the second target device among the at least two devices based on the first frequency information and the second frequency information.

2. The method of claim 1, further comprising:
obtaining frequency ranges corresponding to the at least two devices in the quantum chip layout through simulation;
wherein obtaining the first frequency information of the first target device among the at least two devices of the quantum chip layout through simulation, comprises:
obtaining the first frequency information of the first target device through simulation, based on a frequency range corresponding to the first target device among the frequency ranges corresponding to the at least two devices.

3. The method of claim 2, wherein obtaining the second frequency information of the second target device among the at least two devices through simulation, comprises:
obtaining the second frequency information of the second target device through simulation, based on a frequency range corresponding to the second target device among the frequency ranges corresponding to the at least two devices.

4. The method of claim 2, wherein obtaining the frequency ranges corresponding to the at least two devices in the quantum chip layout through simulation, comprises:
obtaining electric field distribution corresponding to the at least two devices in the quantum chip layout through simulation; and
obtaining the frequency ranges corresponding to the at least two devices based on the electric field distribution corresponding to the at least two devices.

5. The method of claim 1, wherein obtaining the first frequency information of the first target device among the at least two devices of the quantum chip layout through simulation, comprises:
obtaining the first frequency information containing a first normal mode frequency and a first bare mode frequency corresponding to the first target device through simulation, in a case of a coupling type between the first target device and the second target device satisfies a first condition; and
obtaining the second frequency information of the second target device among the at least two devices through simulation, comprises:
obtaining the second frequency information containing a second normal mode frequency and a second bare mode frequency corresponding to the second target device through simulation, in the case of the coupling type between the first target device and the second target device satisfies the first condition.

6. The method of claim 5, wherein obtaining the first frequency information containing the first normal mode frequency and the first bare mode frequency corresponding to the first target device through simulation, comprises:
obtaining the first normal mode frequency of the first target device through simulation;
adjusting a physical parameter of a first adjacent device of the first target device in the quantum chip layout, to decouple the first adjacent device of the first target device from the first target device; and
obtaining the first bare mode frequency corresponding to the first target device through simulation after the decoupling is completed.

7. The method of claim 5, wherein obtaining the second frequency information containing the second normal mode frequency and the second bare mode frequency corresponding to the second target device through simulation, comprises:
obtaining the second normal mode frequency of the second target device through simulation;
adjusting a physical parameter of a second adjacent device of the second target device in the quantum chip layout, to decouple the second adjacent device of the second target device from the second target device; and
obtaining the second bare mode frequency corresponding to the second target device through simulation after the decoupling is completed.

8. The method of claim 5, wherein obtaining the coupling strength between the first target device and the second target device among the at least two devices based on the first frequency information and the second frequency information, comprises:
obtaining first simulation precision information based on the first normal mode frequency and the first bare mode frequency corresponding to the first target device and the second normal mode frequency and the second bare mode frequency corresponding to the second target device; and
calculating the coupling strength between the first target device and the second target device based on the first normal mode frequency and the first bare mode frequency corresponding to the first target device and the second normal mode frequency and the second bare mode frequency corresponding to the second target device, in a case of the first simulation precision information satisfies a first precision requirement.

9. The method of claim 5, wherein the coupling type satisfying the first condition is resonant coupling or non-resonant coupling.

10. The method of claim 1, wherein obtaining the first frequency information of the first target device among the at least two devices of the quantum chip layout through simulation, comprises:
obtaining the first frequency information containing a first normal mode frequency corresponding to the first target device through simulation, in a case of a coupling type between the first target device and the second target device among the at least two devices satisfies a second condition; and
obtaining the second frequency information of the second target device among the at least two devices through simulation, comprises:
obtaining the second frequency information containing a second normal mode frequency corresponding to the second target device through simulation, in the case of the coupling type between the first target device and the second target device among the at least two devices satisfies the second condition.

11. The method of claim 10, wherein obtaining the coupling strength between the first target device and the second target device among the at least two devices based on the first frequency information and the second frequency information, comprises:
obtaining second simulation precision information based on the first normal mode frequency corresponding to the first target device and the second normal mode frequency corresponding to the second target device; and
calculating the coupling strength between the first target device and the second target device based on the first normal mode frequency corresponding to the first target device and the second normal mode frequency corresponding to the second target device, in a case of the second simulation precision information satisfies a second precision requirement.

12. The method of claim 10, wherein the coupling type satisfying the second condition is resonant coupling.

13. An electronic device, comprising:
at least one processor; and
a memory in communication with the at least one processor;
wherein the memory stores an instruction that, when executed by the at least one processor, causes the at least one processor to execute operations comprising:
obtaining first frequency information of a first target device among at least two devices of a quantum chip layout through simulation;
obtaining second frequency information of a second target device among the at least two devices through simulation; and
obtaining a coupling strength between the first target device and the second target device among the at least two devices based on the first frequency information and the second frequency information.

14. The electronic device of claim 13, wherein the operations further comprise:
obtaining frequency ranges corresponding to the at least two devices in the quantum chip layout through simulation;
wherein obtaining the first frequency information of the first target device among the at least two devices of the quantum chip layout through simulation, comprises:
obtaining the first frequency information of the first target device through simulation, based on a frequency range corresponding to the first target device among the frequency ranges corresponding to the at least two devices.

15. The electronic device of claim 14, wherein obtaining the second frequency information of the second target device among the at least two devices through simulation, comprises:
obtaining the second frequency information of the second target device through simulation, based on a frequency range corresponding to the second target device among the frequency ranges corresponding to the at least two devices.

16. The electronic device of claim 14, wherein obtaining the frequency ranges corresponding to the at least two devices in the quantum chip layout through simulation, comprises:
obtaining electric field distribution corresponding to the at least two devices in the quantum chip layout through simulation; and
obtaining the frequency ranges corresponding to the at least two devices based on the electric field distribution corresponding to the at least two devices.

17. A non-transitory computer-readable storage medium storing a computer instruction thereon, wherein the computer instruction causes a computer to execute operations, comprising:
obtaining first frequency information of a first target device among at least two devices of a quantum chip layout through simulation;
obtaining second frequency information of a second target device among the at least two devices through simulation; and
obtaining a coupling strength between the first target device and the second target device among the at least two devices based on the first frequency information and the second frequency information.

18. The storage medium of claim 17, wherein the operations further comprise:
obtaining frequency ranges corresponding to the at least two devices in the quantum chip layout through simulation;
wherein obtaining the first frequency information of the first target device among the at least two devices of the quantum chip layout through simulation, comprises:
obtaining the first frequency information of the first target device through simulation, based on a frequency range corresponding to the first target device among the frequency ranges corresponding to the at least two devices.

19. The storage medium of claim 18, wherein obtaining the second frequency information of the second target device among the at least two devices through simulation, comprises:
obtaining the second frequency information of the second target device through simulation, based on a frequency range corresponding to the second target device among the frequency ranges corresponding to the at least two devices.

20. The storage medium of claim 18, wherein obtaining the frequency ranges corresponding to the at least two devices in the quantum chip layout through simulation, comprises:
obtaining electric field distribution corresponding to the at least two devices in the quantum chip layout through simulation; and
obtaining the frequency ranges corresponding to the at least two devices based on the electric field distribution corresponding to the at least two devices.
